(19) United States
(12) Patent Application Publication
(10) Pub. No.: US 2025/0218840 A1
(43) Pub. Date: Jul. 3, 2025

(54) APPARATUS AND METHOD FOR DETECTING SUBSTRATE STATE

(71) Applicant: SEMES CO., LTD., Cheonan-si (KR)

(72) Inventor: Jae Won SHIN, Seoul (KR)

(21) Appl. No.: 18/887,246

(22) Filed: Sep. 17, 2024

(30) Foreign Application Priority Data
Dec. 27, 2023 (KR) 10-2023-0192480

(51) Int. Cl. H01L 21/68; H01L 21/67

(52) U.S. Cl. CPC H01L 21/68; H01L 21/67259

(57) ABSTRACT

The present disclosure provides an apparatus and method for detecting a substrate state, and provided is the apparatus for detecting a substrate state, including: a substrate transfer unit transferring a substrate; a sensor unit including one or more sensor arrays, and detecting a presence or an absence of the substrate in a position in which the one or more sensor arrays are disposed; and a detection unit detecting an alignment state of the substrate.

### CROSS-REFERENCE TO RELATED APPLICATION(S)

This application claims benefit of priority to Korean Patent Application No. 10-2023-0192480 filed on Dec. 27, 2023, in the Korean Intellectual Property Office, the disclosure of which is incorporated herein by reference in its entirety.

### BACKGROUND

### 1. FIELD

The present disclosure relates to an apparatus and method for detecting a substrate state.

### 2. DESCRIPTION OF RELATED ART

In order to manufacture semiconductors, various types of unit processes are required in stages, and for this purpose, wafers are moved between a plurality of devices performing unit processes by a transfer robot.

In order to ensure processing efficiency and consistency of each unit process, wafers should be aligned in a certain direction in the facility. This is because each unit process is designed to be processed based on a certain direction of a substrate.

Wafers used as semiconductor materials generally have the shape of a disk, and a notch is formed in one position on a circumference, which serves as a reference for aligning the wafers.

Conventionally, a separate aligner has been used to align wafers based on a position in which the notch is formed. If a problem occurs in the software or hardware of the aligner and the wafers are not properly aligned and was put into the facility, there has been a risk of damage to the facility.

### SUMMARY

An aspect of the present disclosure is to provide an apparatus and method for detecting a substrate state which may detect misalignment of a position of a notch while transferring the substrate.

In an embodiment, the present disclosure is to provide an apparatus and method for detecting a substrate state which may detect a position of a center of a substrate, a radius of the substrate, and an alignment state of a notch of the substrate based on an edge position of the substrate detected while transferring the substrate.

In an embodiment, the present disclosure is to provide an apparatus and method for detecting a substrate state which may prevent damage to devices or process errors by detecting the substrate state during a transfer process before the substrate is input into a processing module.

In order to achieve the above-mentioned purpose, the present disclosure provides an apparatus and method for detecting a substrate state as follows.

In an embodiment of the present disclosure, provided is an apparatus for detecting a substrate state, including: a substrate transfer unit transferring a substrate; a sensor unit including one or more sensor arrays, and detecting a presence or an absence of the substrate in a position in which the one or more sensor arrays are disposed; and a detection unit detecting an alignment state of the substrate, and the detection unit detects an edge position of the substrate based on a sensing result of the sensor unit while the substrate is advanced in a first direction by the substrate transfer unit, and detects at least one of an alignment state of a center of the substrate and an alignment state of a notch of the substrate based on the edge position of the substrate.

In an embodiment of the present disclosure, provided is a method for detecting a substrate state, including: transferring a substrate in a first direction; detecting a fifth edge position of the substrate; detecting a center position of the substrate based on the fifth edge position; moving a center of the substrate onto a center line in parallel with the first direction and passing through a target center position of the substrate; detecting a sixth edge position of the substrate; determining an alignment state of a notch of the substrate based on the sixth edge position.

In an embodiment of the present disclosure, provided is an apparatus for detecting a substrate state, including: a substrate transfer unit including a hand for supporting a substrate and transferring the substrate; a sensor unit including one or more sensor arrays including a signal generator and a signal receiver, and sensing a presence or an absence of the substrate on a position in which the one or more sensor arrays are disposed; a detection unit detecting an alignment state of the substrate; and a substrate support unit including a substrate support surface including a target position of the substrate, and the detection unit detects an edge position of the substrate based on a sensing result of the sensor unit while the substrate is advanced in a first direction by the substrate transfer unit, and detects a position of a center of the substrate and an alignment state of a notch of the substrate based on the edge position of the substrate, and the one or more sensor arrays include a first sensor disposed on a notch line in parallel with the first direction and passing through a target notch position of the substrate.

The present disclosure may provide an apparatus and method for detecting a substrate state which may detect a misalignment of a position of a notch while transferring the substrate.

In an embodiment, the present disclosure may provide an apparatus and method for detecting a substrate state which may detect a position of a center of a substrate, a radius of the substrate, and an alignment state of a notch of the substrate based on an edge position of the substrate detected while transferring the substrate.

In an embodiment, the present disclosure may provide an apparatus and method for detecting a substrate state which may prevent damage to devices or process errors by detecting the substrate state during a transfer process before the substrate is input into a processing module.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 schematically illustrates a substrate processing system including an apparatus for detecting a substrate state according to an embodiment of the present disclosure;

FIG. 2 is a block diagram of an apparatus for detecting a substrate state according to an embodiment of the present disclosure;

FIG. 3A is a diagram exemplarily illustrating the operation of a sensor array according to the present disclosure;

FIG. 3B is a view exemplarily illustrating the operation of a sensor array according to the present disclosure;

FIG. 4 is an exemplary view illustrating a method for detecting a substrate state according to an embodiment of the present disclosure;

FIG. 5 is an exemplary view illustrating a method for detecting a substrate state according to an embodiment of the present disclosure;

FIG. 6 is an exemplary view illustrating a method for detecting a substrate state according to an embodiment of the present disclosure;

FIG. 7 is an exemplary view illustrating a method for detecting a substrate state according to an embodiment of the present disclosure;

FIG. 8 is an exemplary view illustrating a method for detecting a substrate state according to an embodiment of the present disclosure;

FIG. 9 is an exemplary view illustrating a method for detecting a substrate state according to an embodiment of the present disclosure;

FIG. 10 is an exemplary view illustrating a method for detecting a substrate state according to an embodiment of the present disclosure;

FIG. 11 is an exemplary view illustrating a method for detecting a substrate state according to an embodiment of the present disclosure;

FIG. 12 is an exemplary view illustrating a method for detecting a substrate state according to an embodiment of the present disclosure;

FIG. 13 is an exemplary view illustrating a portion of a method for detecting a substrate state according to an embodiment of the present disclosure; and

FIG. 14 is a flowchart of a method for detecting a substrate state according to an embodiment of the present disclosure.

### DETAILED DESCRIPTION

Hereinafter, preferred example embodiments will be described in detail with reference to the accompanying drawings so that those of ordinary skill in the art may easily implement the present disclosure. However, in describing preferred example embodiments of the present disclosure in detail, when it is determined that a detailed description of related known functions or configurations may unnecessarily obscure the gist of the present disclosure, the detailed description thereof will be omitted. Furthermore, the same reference numbers are used throughout the drawings to refer to the same or similar functions and actions. In the present specification, it may be understood that the expressions such as “on,” “above,” “upper,” “below”, “beneath,” “lower,” and “side,” merely indicated based on drawings, and may actually vary depending on the direction in which the components are disposed.

Furthermore, throughout the specification, the terms “connected to” or “coupled to” are used to designate a connection or coupling of one element to another element and include both a case where an element is “directly connected or coupled to” another element and a case where an element is “indirectly connected or coupled to” another element via still another element. Furthermore, when a certain portion “includes” or “comprises” a certain component, this indicates that other components are not excluded and may be further included unless otherwise noted.

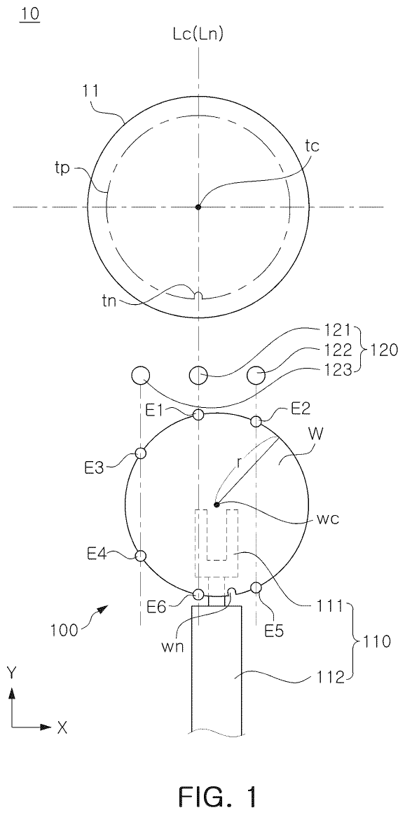

FIG. 1 schematically illustrates a substrate processing system including an apparatus for detecting a substrate state according to an embodiment of the present disclosure. FIG. 1 schematically illustrates a top view of a substrate processing system 10, and as illustrated in FIG. 1, the substrate processing system 10 may include a substrate support unit 11 and an apparatus 100 for detecting a substrate state.

The apparatus 100 for detecting a substrate state according to an embodiment of the present disclosure may detect a state of a substrate W while the substrate W is transferred to the substrate support unit 11. The state of the substrate W may include, for example, an alignment state of a center wc of the substrate or an alignment state of a notch wn of the substrate.

The substrate support unit 11 may include a substrate support surface supporting the substrate W. The substrate support surface may include a target position tp, a target center position tc and a target notch position tn of the substrate W, in which the substrate W transferred by the apparatus 100 for detecting a substrate state is to be disposed,

The substrate support unit 11 may include, for example, an electrostatic chuck absorbing the substrate W by electrostatic force.

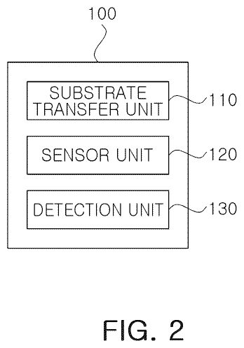

FIG. 2 is a block diagram of an apparatus 100 for detecting a substrate state according to an embodiment of the present disclosure. Referring to FIG. 1 and FIG. 2 together, the apparatus 100 for detecting a substrate state may include a substrate transfer unit 110 and a sensor unit 120.

The substrate transfer unit 110 may transfer the substrate W. The substrate transfer unit 110 may include a hand 111 supporting the substrate W, and a hand support portion 112 connected to one end of the hand 111 and supporting the hand 111.

The substrate transfer unit 110 may support a portion of a lower surface of the substrate W from a lower portion thereof by the hand 111, and may transfer the substrate W by moving the hand 111 and the hand support portion 112.

The substrate transfer unit 110 may move the substrate W in either the first direction or the second direction. A first direction may be a direction from a pre-transfer position of the substrate W toward the target position tp of the substrate W, and a second direction may be a direction, perpendicular to the first direction, on a plane parallel to the surface of the substrate W. For example, the first direction may be a Y-axis direction, and the second direction may be an X-axis direction.

The sensor unit 120 may include one or more sensor arrays. The sensor array may include a signal generator and a signal receiver.

The sensor unit 120 may sense the presence or absence of the substrate W in a position in which one or more sensor arrays are disposed. For example, one or more sensor arrays may be disposed on a path along which the substrate W is transferred by the substrate transfer unit 110.

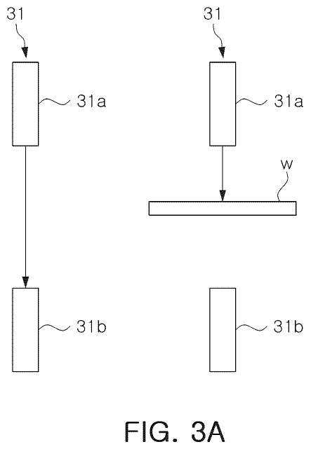

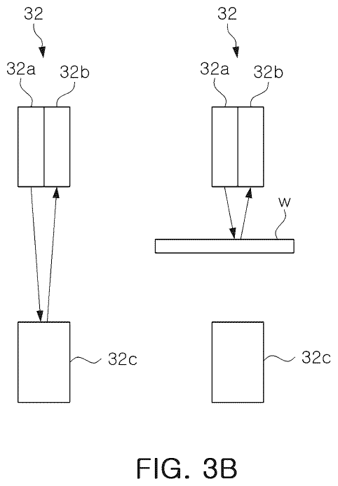

FIGS. 3A and 3B illustrate an operating principle of a sensor array.

As illustrated in FIG. 3A, a sensor array 31 may include a signal generator 31a in an upper portion thereof and a signal receiver 31b in a lower portion thereof. The signal generator 31a and the signal receiver 31b may be disposed to face each other with a predetermined interval.

When there is no substrate W between the signal generator 31a and the signal receiver 31b, a signal generated by the signal generator 31a may be received by the signal receiver 31b.

However, when there is a substrate W between the signal generator 31a and the signal receiver 31b, the signal generated by the signal generator 31a is blocked by the substrate W and does not reach the signal receiver 31b.

The sensor array 31 may generate the signal by the signal generator 31a, and may sense the presence or absence of the substrate W in a corresponding position based on whether the signal reaches the signal receiver 31b.

Additionally, as illustrated in FIG. 3B, a sensor array 32 may include a signal generator 32a and a signal receiver 32b in an upper portion thereof and a signal reflection member 32c in a lower portion thereof. The signal generator 32a and the signal reflection member 32c may be disposed to face each other with a predetermined interval.

When there is no substrate W between the signal generator 32a and the signal reflection member 32c, a signal generated by the signal generator 32a may be reflected from the signal reflection member 32c after reaching the signal reflection member 32c, and the signal reflected from the signal reflection member 32c may be received by the signal receiver 32b.

However, when there is a substrate W between the signal generator 32a and the signal reflection member 32c, the signal generated by the signal generator 32a is blocked by the substrate W and does not reach the signal reflection member 32c. The signal generated by the signal generator 32a may be reflected from the surface of the substrate W closer than the signal reflection member 32c, and the signal reflected from the surface of the substrate W may be received by the signal receiver 32b. In this case, the time required for the signal receiver 32b to receive the reflected signal is less than when the substrate W is not present between the signal generator 32a and the signal reflection member 32c.

That is, the sensor array 32 may generate a signal by the signal generator 32a, and may sense the presence or absence of the substrate W in a corresponding location based on the time required for the signal receiver 32b to receive the reflected signal.

One or more sensor arrays may include, for example, a first sensor 121, a second sensor 122, and a third sensor 123. The first sensor 121, the second sensor 122, and the third sensor 123 may be implemented by either the sensor array 31 illustrated in FIG. 3A or the sensor array 32 illustrated in FIG. 3B.

One or more sensor arrays may be disposed on a path along which the substrate W passes between a pre-transfer position of the substrate W and the target position tp of the substrate W.

The first sensor 121 may be disposed on a notch line Ln. The notch line In may refer to a straight line in parallel with the first direction and passing through a target notch position tn of the substrate W.

The second sensor 122 may be spaced apart from the first sensor 121 and the third sensor 123 and may be disposed outside of the notch line Ln. Additionally, the third sensor 123 may be spaced apart from the first sensor 121 and the second sensor 122 and may be disposed outside of the notch line Ln.

In an embodiment, the first sensor 121, the second sensor 122 and the third sensor 123 may be disposed side by side in the second direction. An internal between the first sensor 121 and the second sensor 122, an internal between the first sensor 121 and the third sensor 123, and an internal spacing between the second sensor 122 and the third sensor 123 may have different values.

In another embodiment, the first sensor 121, the second sensor 122 and the third sensor 123 may be disposed side by side at predetermined intervals in the second direction.

Referring back to FIG. 2, the apparatus 100 for detecting a substrate state may further include a detection unit 130. The detection unit 130 may detect an alignment state of the substrate W.

The detection unit 130 may detect an edge position of the substrate W based on a detection result of the sensor unit 120 while the substrate W is advanced in the first direction by the substrate transfer unit 110.

In a case illustrated in FIG. 1, when the substrate W is advanced in the first direction from the pre-transfer position toward the target position tp, a first edge position E1 sensed first by the first sensor 121 may be detected, a second edge position E2 sensed first by the second sensor 122 may be detected, and then, a third edge position E3 sensed first by the third sensor 123 may be detected.

For example, while the substrate W is advanced in the first direction, a position in which the substrate W is changed from not being detected by the first sensor 121 to being detected may be the first edge position E) of the substrate W.

Then, when the substrate W continues to be advanced in the first direction without a position movement in the second direction, a fourth edge position E4 may be detected by the third sensor 123, a fifth edge position E5 may be detected by the second sensor 122, and then, a sixth edge position E6 may be detected by the first sensor 121. When there is a position movement of the substrate W in the second direction, an edge position different from the fourth to sixth edge positions described above may be detected according to the position movement in the second direction.

For example, while the substrate W is advanced in the first direction without the position movement in the second direction, a position in which the substrate W is changed from being detected by the first sensor 121 to not being detected may be a sixth edge position E6 of the substrate W.

The detection unit 130 may detect at least one of a position of the center wc of the substrate and an alignment state of the notch wn of the substrate based on the edge position of the substrate W.

The detection unit 130 may detect the position of the center wc of the substrate and a radius r of the substrate based on the first edge position E1, the second edge position E2, and the third edge position E3.

For example, the detection unit 130 may detect coordinate values of the first edge position E1, the second edge position E2, and the third edge position E3, and may calculate coordinate values of the center wc of the substrate and the radius r of the substrate in consideration of a movement distance of the substrate W by the substrate transfer unit 110.

The substrate transfer unit 110 may move the substrate W in the second direction based on the calculated coordinate values of the center wc of the substrate, so that the center wc of the substrate is disposed on a center line Lc. The center line Lc may refer to a straight line in parallel with the first direction and passing through a target center position tc of the substrate W.

The detection unit 130 may calculate a determination distance from an edge position in which the substrate W is last sensed by the first sensor 121 to the center wc of the substrate while the substrate W is advanced in the first direction.

The detection unit 130 may detect the alignment state of the notch wn of the substrate based on a result of comparing the determination distance with the radius r of the substrate.

For example, the detection unit 130 may determine the alignment state of the notch wn of the substrate to be abnormal when the determination distance matches the radius r of the substrate.

Additionally, the detection unit 130 may determine the alignment state of the notch wn of the substrate to be normal when the determination distance does not match the radius r of the substrate and matches a first reference distance.

The first reference distance may refer to a distance between the center wc of the substrate and the notch wn of the substrate. More specifically, the first reference distance may refer to a distance between a point at which a notch outline of the substrate W meets the notch line In and the center wc of the substrate when the center wc of the substrate is disposed on the center line Lc.

Hereinafter, a method for detecting a substrate state performed by the apparatus 100 for detecting a substrate state according to an embodiment of the present disclosure will be described through specific examples.

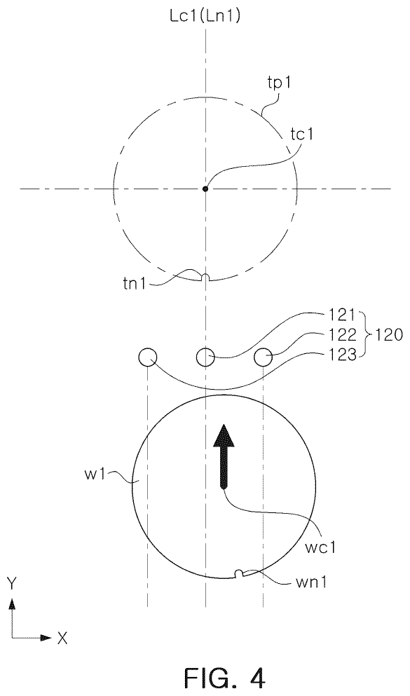

FIGS. 4 to 8 sequentially illustrate a method of detecting a state of a first substrate w1 using the apparatus 100 for detecting a substrate state. In FIGS. 4 to 8, for the sake of explanation, some of apparatus components are omitted and a position of the first substrate w1 will mainly be described.

Referring to FIG. 4, tp1 represents a target position of the first substrate w1, tc1 represents a target center position to which a center wc1 of the first substrate should be moved, and tn1 represents a target notch position to which a notch wn1 of the first substrate should be moved.

FIGS. 4 to 8 illustrate a case in which a target center position tc1 and a target notch position tn1 are disposed on the same straight line in the Y-direction. That is, FIGS. 4 to 8 illustrate a case in which a center line Lc1 and a notch line Ln1 match each other.

As illustrated in FIG. 4, one or more sensor arrays may be disposed on a path along which the first substrate w1 is moved from the pre-transfer position toward a target position tp1.

The first sensor 121 may be disposed on the notch line Ln1, and the second sensor 122 and the third sensor 123 may be disposed outside of the notch line In1 and may be spaced apart from the first sensor 121 by a predetermined distance.

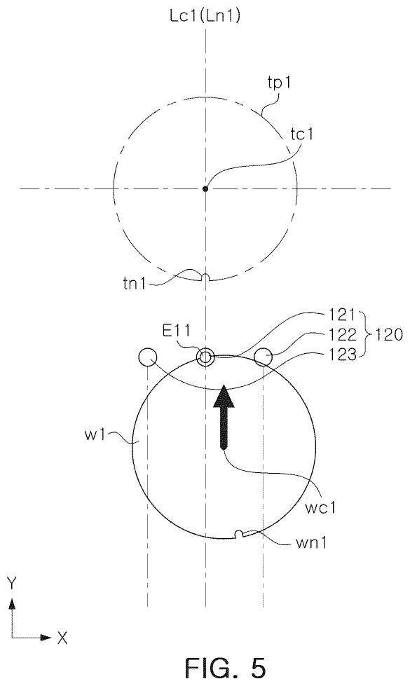

Referring to FIG. 5, as the first substrate w1 is advanced in the Y-direction, a first edge position E11 of the first substrate w1 may be detected by the first sensor 121.

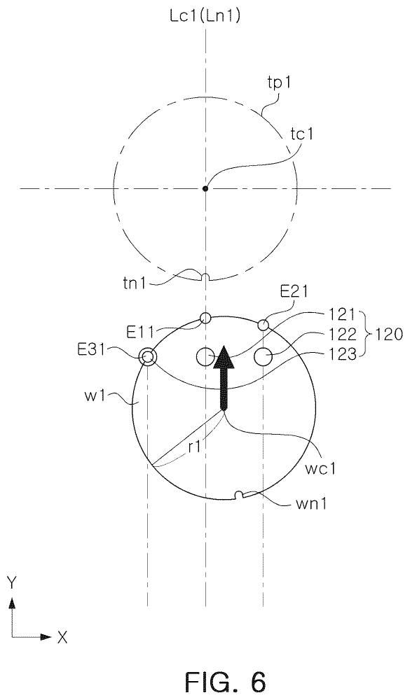

As the first substrate w1 continues to be advanced in the Y-direction, as illustrated in FIG. 6, a second edge position E21 may be detected by the second sensor 122, and a third edge position E31 may be detected by the third sensor 123.

The apparatus 100 for detecting a substrate state may detect the position of the center wc1 of the first substrate and a radius r1 of the first substrate based on the first edge position E11, the second edge position E21 and the third edge position E31.

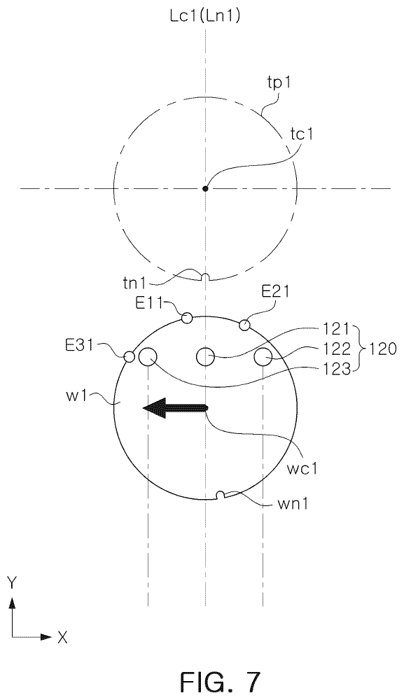

As illustrated in FIG. 7, the first substrate w1 may be moved in the X-direction so that the center wc1 of the first substrate is disposed on the center line Lc1.

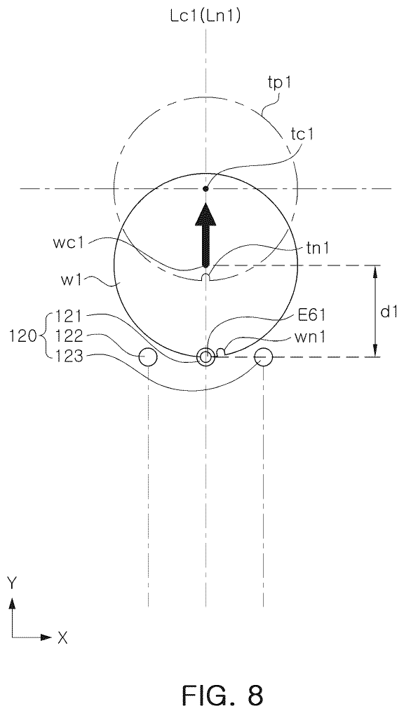

Subsequently, the first substrate w1 may be moved in the Y-direction toward the target position tp1. Referring to FIG. 8, as the first substrate w1 is advanced in the Y-direction, a sixth edge position E61 of the first substrate w1 may be detected by the first sensor 121.

The apparatus 100 for detecting a substrate state may calculate a first determination distance d1 from the sixth edge position E61 to the center wc1 of the first substrate, and may detect an alignment state of the notch wn1 of the first substrate based on a result of comparing the first determination distance d1 and the radius r1 of the first substrate.

For example, as illustrated in FIG. 8, when the first determination distance d1 and the radius r1 of the first substrate have the same value, the notch wn1 of the first substrate may not be disposed in the sixth edge position E61, and the notch wn1 of the first substrate may not be disposed in the notch line Ln1, so that the alignment state of the notch wn1 of the first substrate may be determined to be abnormal.

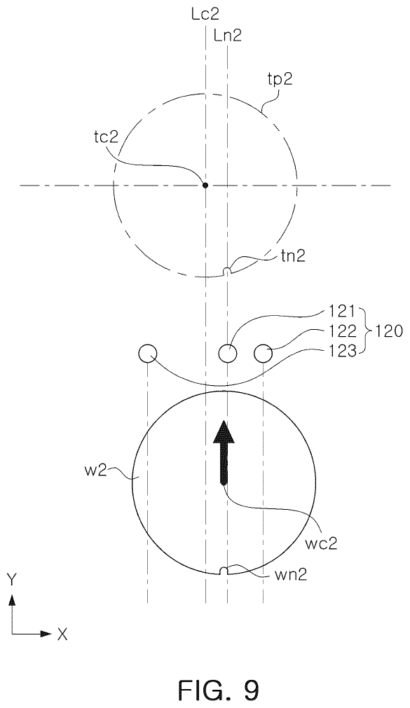

FIGS. 9 to 13 sequentially illustrate a method for detecting a state of a second substrate w2 using the apparatus 100 for detecting a substrate state. In FIGS. 9 to 13, for the sake of explanation, some of apparatus components are omitted and a position of the second substrate w2 will be mainly described.

Referring to FIG. 9, tp2 represents a target position of the second substrate w2, tc2 represents a target center position to which a center wc2 of the second substrate should be moved, and tn2 represents a target notch position to which a notch wn2 of the second substrate should be moved.

FIGS. 9 to 13 illustrate a case in which a target center position tc2 and a target notch position tn2 are disposed on different straight lines in the Y-direction.

That is, unlike the case illustrated in FIGS. 4 to 8, FIGS. 9 to 13 illustrate a case in which a center line Lc2 and a notch line Ln2 do not match each other.

As illustrated in FIG. 9, one or more sensor arrays may be disposed on a path along which the second substrate w2 is transferred from a pre-transport position toward a target position tp2.

The first sensor 121 may be disposed on a notch line Ln2, and the second sensor 122 and the third sensor 123 may be disposed outside of the notch line Ln2 and may be spaced apart from the first sensor 121 by a predetermined distance.

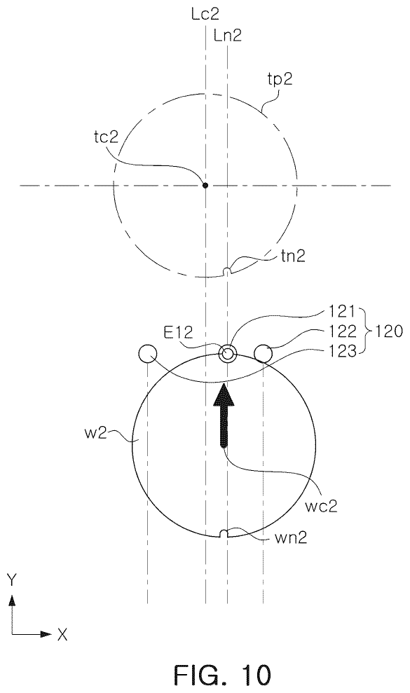

Referring to FIG. 10, as the second substrate w2 is advanced in the Y-direction, a first edge position E12 of the second substrate w2 may be detected by the first sensor 121.

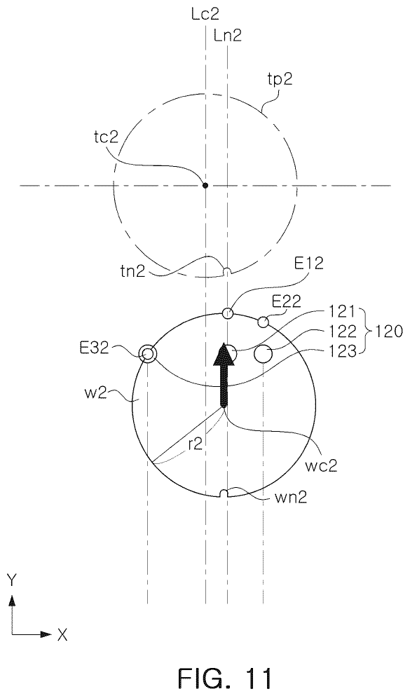

As the second substrate w2 continues to be advanced in the Y-direction, as illustrated in FIG. 11, a second edge position E22 may be detected by the second sensor 122, and a third edge position E32 may be detected by the third sensor 123.

The apparatus 100 for detecting a substrate state may detect a position of the center wc2 of the second substrate and a radius r2 of the second substrate based on the first edge position E12, the second edge position E22 and the third edge position E32.

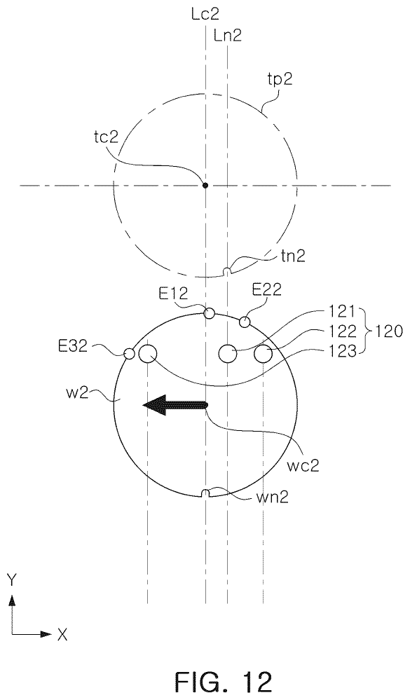

As illustrated in FIG. 12, the second substrate w2 may be moved in the X-direction so that the center wc2 of the second substrate is disposed on the center line Lc2.

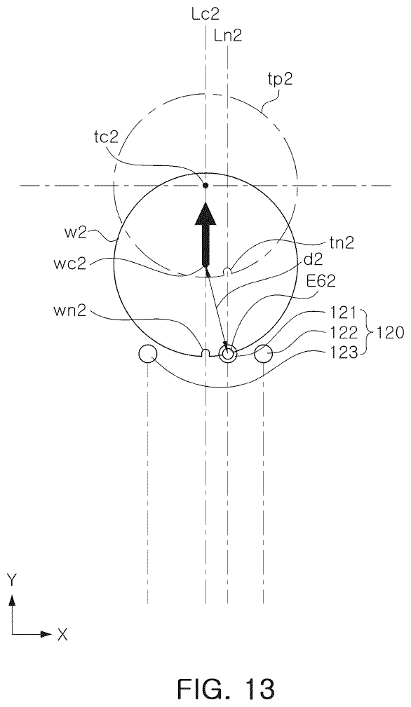

Next, the second substrate w2 may be moved in the Y-direction toward the target position tp2. Referring to FIG. 13, as the second substrate w2 is advanced in the Y-direction, a sixth edge position E62 of the second substrate w2 may be detected by the first sensor 121.

The apparatus 100 for detecting a substrate state may calculate a second determination distance d2 from the sixth edge position E62 to the center wc2 of the second substrate, and may detect an alignment state of the notch wn2 of the second substrate based on a result of comparing the second determination distance d2 and the radius r2 of the second substrate.

For example, as illustrated in FIG. 13, when the second determination distance d2 and the radius r2 of the second substrate have the same value, the notch wn2 of the second substrate may not be disposed in the sixth edge position E62, and the notch wn2 of the second substrate may not be disposed on the notch line Ln2, so that the alignment state of the notch wn2 of the second substrate may be determined to be abnormal.

FIGS. 9 to 13 are exemplary views illustrating a method for detecting a substrate state according to another embodiment of the present disclosure.

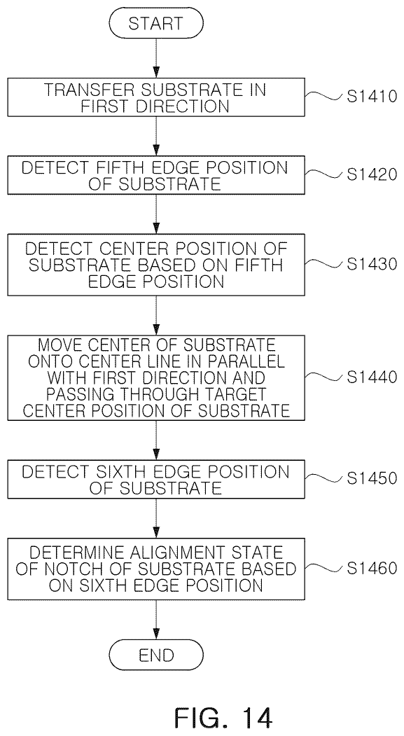

FIG. 14 is a flowchart of a method for detecting a substrate state according to an embodiment of the present disclosure. As illustrated in FIG. 14, a method for detecting a substrate state (1400) may include: an operation of transferring a substrate in a first direction (S1410); an operation of detecting a fifth edge position of the substrate (S1420); an operation of detecting a center position of the substrate based on the fifth edge position (S1430); an operation of moving a center of the substrate onto a center line in parallel with the first direction and passing through a target center position of the substrate (S1440); an operation of detecting a sixth edge position of the substrate (S1450); and an operation of determining an alignment state of a notch of the substrate based on the sixth edge position (S1460).

In the operation of transferring the substrate in the first direction (S1410), the first direction may be a direction from a pre-transfer position of the substrate toward a target position of the substrate.

The operation of detecting the fifth edge position of the substrate (S1420) may include position information of three or more points disposed on an edge of the substrate.

In the operation of moving the center of the substrate (S1440), the substrate may be moved in a second direction. The second direction may be a direction, perpendicular to the first direction, on a plane parallel to the surface of the substrate.

In the operation of detecting the sixth edge position of the substrate (S1450), the sixth edge position may include position information of a notch line in parallel with the first direction and passing through a target notch position of the substrate and a reference point disposed on an edge of the substrate.

The operation of determining the alignment state of the notch of the substrate (S1460) may include an operation of calculating a radius of the substrate based on the fifth edge position.

The operation of determining the alignment of the notch of the substrate (S1460) may further include an operation of calculating a determination distance from a reference point to the center of the substrate based on the sixth edge position, the position of the center of the substrate, and the transfer distance of the substrate.

The operation of determining the alignment of the notch of the substrate (S1460) may further include an operation of comparing the determination distance with the radius of the substrate. In the operation of comparing the determination distance with the radius of the substrate, when the determination distance matches the radius of the substrate, the alignment of the notch of the substrate may be determined to be abnormal.

The operation of comparing the determination distance with the radius of the substrate may include an operation of calculating a reference distance and an operation of comparing the determination distance with the reference distance. The reference distance may be the distance between a point at which an outline of the notch of the substrate meets the notch line and the center of the substrate when the center of the substrate is disposed on the center line.

In the operation of comparing the determination distance with the reference distance, when the determination distance matches the reference distance, the alignment of the notch of the substrate may be determined to be normal. Additionally, in describing the present disclosure,

‘˜ portion’ or ‘unit’ may be implemented in various manners, for example, by a processor, program instructions executed by the processor, a software module, a microcode, a computer program product, a logic circuit, an application-specific integrated circuit, firmware, or the like.

The contents of the method disclosed in the embodiment of the present application may be directly implemented by a hardware processor, or may be implemented and performed by a combination of hardware and software modules among the processors. The software module may be stored in a conventional storage medium such as a random-access memory, a flash memory, a read-only memory, a programmable read-only memory, an electrically erasable programmable memory, a register, or the like. The storage medium is disposed in the memory, and the processor reads the information stored in the memory and combines the information with the hardware to complete the contents of the above-described method. In order to avoid duplication, a detailed description is omitted herein.

In the implementation process, each content of the above-described method may be completed by a logical integrated circuit of the hardware among the processors or an instruction in the form of software.

That is, those skilled in the art may recognize that each exemplary unit and algorithm operation described in the embodiments disclosed herein may be realized by combining electronic hardware or a combination of computer software and electronic hardware. Whether such a function is performed in a hardware manner or in a software manner is determined by specific application and design constraints of the technical solution. Those skilled in the art may realize the described function using different methods for each specific application, but such realization should not be considered as being outside the scope of the present application.

It should be understood that in the several embodiments provided in the present application, the disclosed apparatus and method may be realized in other manners. For example, the apparatus embodiments described above are merely exemplary, for example, the division of the units is merely a kind of logical functional division, and other division methods may exist in actual implementation, and for example, a plurality of units or assemblies may be combined or integrated into another system, or some features may be ignored or not performed. On the other hand, the coupling or direct coupling or communication connection between each other displayed or discussed may be an indirect coupling or communication connection through some interface, apparatus or unit, and may be provided in an electrical, mechanical or other form.

The unit described as a separate component above may be physically separated, and the component displayed as a unit may or may not be a physical unit, that is, disposed in one point or distributed in a plurality of network units. Some or all of the units may be selected according to actual needs to realize the purpose of the solution of the present embodiment.

That is, each functional unit in each embodiment of the present application may be integrated into one processing unit, and each unit may exist alone, or two or more units may be integrated into one unit.

When the function is implemented in the form of a software functional unit and sold or used as an independent product, this may be stored in one computer-readable storage medium. Based on this understanding, a portion that essentially contributes to the prior art in technical t solution of the present application, or a portion of the technical solution, may be implemented in the form of a software product, and the computer software product is stored in one storage medium, and includes a few instructions to cause one computer device (which may be a personal computer, a server, or a network device, or the like) to perform all or part of the operations of the method described in each embodiment of the present application. The storage medium described above includes various media capable of storing program codes, such as a USB memory, a mobile hard disk, a read-only memory (ROM), a random-access memory (RAM), a magnetic disk, a CD-ROM or the like.

The present disclosure is not limited to the embodiment described above and the accompanying drawings. The scope of rights of the present disclosure is intended to be limited by the appended claims. It will be understood by those skilled in the art that various substitutions, modification and changes in form and details may be made therein without departing from the spirit and scope of the present disclosure as defined by the appended claims.

What is claimed is:

1. An apparatus for detecting a substrate state, comprising:
a substrate transfer unit transferring a substrate;
a sensor unit including one or more sensor arrays, and detecting a presence or an absence of the substrate in a position in which the one or more sensor arrays are disposed; and
a detection unit detecting an alignment state of the substrate,
wherein the detection unit detects an edge position of the substrate based on a sensing result of the sensor unit while the substrate is advanced in a first direction by the substrate transfer unit, and detects at least one of an alignment state of a center of the substrate and an alignment state of a notch of the substrate based on the edge position of the substrate.

2. The apparatus for detecting a substrate state according to claim 1, wherein the first direction is a direction from a pre-transfer position of the substrate toward a target position of the substrate, and the one or more sensor arrays are disposed on a path along which the substrate passes between the pre-transfer position of the substrate and the target position of the substrate.

3. The apparatus for detecting a substrate state according to claim 2, wherein the one or more sensor arrays include:
a first sensor disposed on a notch line in parallel with the first direction and passing through a target notch position of the substrate;
a second sensor spaced apart from the first sensor and disposed outside of the notch line; and
a third sensor spaced apart from the first sensor and the second sensor and disposed outside of the notch line.

4. The apparatus for detecting a substrate state according to claim 3, wherein an edge position of the substrate includes:
a first edge position of the substrate initially sensed by the first sensor while the substrate is advanced in the first direction by the substrate transfer unit;
a second edge position of the substrate initially sensed by the second sensor while the substrate is advanced in the first direction by the substrate transfer unit; and
a third edge position of the substrate initially sensed by the third sensor while the substrate is advanced in the first direction by the substrate transfer unit, wherein the detection unit detects a position of the center of the substrate and a radius of the substrate based on the first edge position, the second edge position, and the third edge position.

5. The apparatus for detecting a substrate state according to claim 4, wherein the substrate transfer unit moves the center of the substrate onto a center line in parallel with the first direction and passing through a target center position of the substrate based on the position of the center of the substrate.

6. The apparatus for detecting a substrate state according to claim 5, the substrate transfer unit moves the center of the substrate in a second direction, perpendicular to the first direction, on a plane parallel to a surface of the substrate.

7. The apparatus for detecting a substrate state according to claim 6, wherein the edge position of the substrate further includes a fourth edge position of the substrate last sensed by the first sensor while the substrate is advanced in the first direction by the substrate transfer unit, and
wherein the detection unit calculates a determination distance from the fourth edge position to the center of the substrate, and detects an alignment state of the notch of the substrate based on a result of comparing the determination distance with the radius of the substrate.

8. The apparatus for detecting a substrate state according to claim 7, wherein the detection unit determines the alignment state of the notch of the substrate to be abnormal when the determination distance matches the radius of the substrate.

9. The apparatus for detecting a substrate state according to claim 8, wherein the first reference distance is a distance between a point at which a notch outline of the substrate meets the notch line and the center of the substrate when the center of the substrate is disposed on the center line,
wherein the detection unit determines the alignment state of the notch of the substrate to be normal when the determination distance matches the first reference distance.

10. The apparatus for detecting a substrate state according to claim 3, wherein the first sensor, the second sensor, and the third sensor are disposed side by side in a second direction, perpendicular to the first direction, on a plane parallel to a surface of the substrate, and
wherein an interval between the first sensor and the second sensor, an interval between the first sensor and the third sensor, and an interval between the first sensor and the second sensor have different values.

11. A method for detecting a substrate state, the method comprising:
transferring a substrate in a first direction;
detecting a fifth edge position of the substrate;
detecting a center position of the substrate based on the fifth edge position;
moving a center of the substrate onto a center line in parallel with the first direction and passing through a target center position of the substrate;
detecting a sixth edge position of the substrate;
determining an alignment state of a notch of the substrate based on the sixth edge position.

12. The method for detecting a substrate state according to claim 11, wherein the first direction is a direction from a pre-transfer position of the substrate toward a target position of the substrate, and
wherein in the detecting a fifth edge position of the substrate, the fifth edge position includes position information of three or more points disposed on an edge of the substrate.

13. The method for detecting a substrate state according to claim 12, wherein in the moving a center of the substrate, the center of the substrate is moved in a second direction, perpendicular to the first direction, on a plane parallel to a surface of the substrate.

14. The method for detecting a substrate state according to claim 13, wherein in the detecting a sixth edge position of the substrate, the sixth edge position includes position information of a reference point disposed on a notch line in parallel with the first direction and passing through a target notch position of the substrate.

15. The method for detecting a substrate state according to claim 14, wherein the determining an alignment state of a notch of the substrate includes:
calculating a radius of the substrate based on the fifth edge position;
calculating a determination distance from the reference point to the center of the substrate based on the sixth edge position, a position of the center of the substrate, and a transfer distance of the substrate; and
comparing the determination distance with the radius of the substrate.

16. The method for detecting a substrate state according to claim 15, wherein in the determining an alignment state of a notch of the substrate, the alignment state of the notch of the substrate is determined to be abnormal when the determination distance matches the radius of the substrate.

17. The method for detecting a substrate state according to claim 16, wherein the determining an alignment state of a notch of the substrate includes:
calculating a reference distance between a point at which an outline of the notch of the substrate meets the notch line and the center of the substrate when the center of the substrate is disposed on the center line; and
comparing the determination distance with the reference distance.

18. The method for detecting a substrate state according to claim 17, wherein in the determining an alignment state of a notch of the substrate, the alignment state of the notch of the substrate is determined to be normal when the determination distance matches the reference distance.

19. An apparatus for detecting a substrate state, comprising:
substrate a transfer unit including a hand for supporting a substrate and transferring the substrate;
a sensor unit including one or more sensor arrays including a signal generator and a signal receiver, and sensing a presence or an absence of the substrate on a position in which the one or more sensor arrays are disposed;
a detection unit detecting an alignment state of the substrate; and
a substrate support unit including a substrate support surface including a target position of the substrate,
wherein the detection unit detects an edge position of the substrate based on a sensing result of the sensor unit while the substrate is advanced in a first direction by the substrate transfer unit, and detects a position of a center of the substrate and an alignment state of a notch of the substrate based on the edge position of the substrate, and
wherein the one or more sensor arrays include a first sensor disposed on a notch line in parallel with the first direction and passing through a target notch position of the substrate.

20. The apparatus for detecting a substrate state according to claim 19, wherein the one or more sensor arrays further include:
a second sensor spaced apart from the first sensor and disposed outside of the notch line; and
a third sensor spaced apart from the first sensor and the second sensor and disposed outside of the notch line,
wherein the detection unit detects a center position and a radius of the substrate based on an edge position initially sensed by the first sensor, an edge position initially sensed by the second sensor, and an edge position initially sensed by the third sensor while the substrate is advanced in the first direction by the substrate transfer unit, and
the detection unit detects the alignment state of the notch of the substrate based on an edge position last sensed by the first sensor while the substrate is advanced in the first direction by the substrate transfer unit.
